(19) United States
(12) Patent Application Publication
(10) Pub. No.: US 2025/0311162 A1
(43) Pub. Date: Oct. 2, 2025

(54) HEAT DISSIPATION DEVICE FOR INDUSTRIAL COMPUTER

(71) Applicant: CINCOZE CO., LTD., New Taipei City (TW)

(72) Inventor: HSIN-TE CHIEN, New Taipei City (TW)

(73) Assignee: CINCOZE CO., LTD., New Taipei City (TW)

(21) Appl. No.: 18/736,583

(22) Filed: Jun. 7, 2024

(30) Foreign Application Priority Data
Mar. 27, 2024 (TW) 113111471

(51) Int. Cl. H05K 7/20; G06F 1/20

(52) U.S. Cl. CPC H05K 7/2039; G06F 1/206

(57) ABSTRACT

A heat dissipation device for an industrial computer includes a heat dissipation unit, adjustment units, and fixation units. The adjustment units are disposed on two sides of the heat dissipation unit. The fixation units are movably disposed at the adjustment units. Thus, to allow the heat dissipation unit to be coupled to the industrial computer, the fixation units are moved within the adjustment units to perform positional adjustment and thereby enable the fixation units to precisely correspond in position to fastening holes of the industrial computer during a fastening process, allowing the heat dissipation unit to be in full contact with a processor of the industrial computer.

### CROSS-REFERENCE TO RELATED APPLICATION

This non-provisional application claims priority under 35 U.S.C. § 119(a) on Patent Application No(s). 113111471 filed in Taiwan, R.O.C. on Mar. 27, 2024, the entire contents of which are hereby incorporated by reference.

### BACKGROUND OF THE INVENTION

### 1. Field of the Invention

The present disclosure relates to heat dissipation devices for industrial computers, and in particular to a heat dissipation device for an industrial computer, achieving enhanced ease of mounting, firm fastening, enhanced heat conduction efficiency, and satisfactory heat dissipation effect.

### 2. Description of the Related Art

A conventional heat dissipation system for an industrial computer typically comes with a heat conduction medium that comprises an internal metallic heat dissipation block and an external heat dissipation aluminum casing. The internal metallic heat dissipation block and the external heat dissipation aluminum casing have to be fixed in place by a fastening means to ensure that the internal metallic heat dissipation block is in full contact with a processor.

However, the manufacturing process of metallic components inevitably leads to challenges of tolerance. As a result, dislocated fastening holes lower the chance of full contact between the heat dissipation block and the processor to the detriment of the functioning of heat conduction medium, reducing the efficiency of heat conduction between the metallic components. Furthermore, unpredictable factors in an assembly process (for example, a fastening technique and magnitude of a fastening force) add to the difficulties in attaining the full contact between the heat dissipation block and the processor after they have been fastened and fixed in place.

### BRIEF SUMMARY OF THE INVENTION

In view of the aforesaid drawbacks of the prior art, it is an objective of the present disclosure to provide a heat dissipation device for an industrial computer to enhance the precision of a fastening process and thereby ensure the full contact between a heat dissipation unit and a processor of an industrial computer, achieving enhanced ease of mounting, firm fastening, enhanced heat conduction efficiency, and satisfactory heat dissipation effect.

To achieve the above and other objectives, the present disclosure provides a heat dissipation device for an industrial computer. The heat dissipation device comprises a heat dissipation unit, at least two adjustment units, and at least two fixation units. The adjustment units are disposed on at least two sides of the heat dissipation unit. The fixation units are movably disposed at the adjustment units.

In an embodiment of the present disclosure, the heat dissipation unit comprises a base, a heatsink module and a contact portion, with the heatsink module disposed on a top surface of the base, and the contact portion disposed on a bottom surface of the base, allowing the adjustment units to be disposed on lateral sides of the base.

In an embodiment of the disclosure, the heat dissipation unit comprises a base, a heatsink module, a contact portion, a fitting portion, and a guiding module, with the heatsink module disposed on a top surface of the base, the contact portion disposed on a bottom surface of the base, the fitting portion disposed at the heatsink module, the guiding module coupled to the fitting portion and disposed on a top surface of the heatsink module, allowing the adjustment units to be disposed on lateral sides of the base.

In an embodiment of the present disclosure, a first free space is centrally disposed at each of the adjustment units, with a second free space, and a third free space disposed on two sides of each of the adjustment units, with a first position-limiting portion disposed on a top surface of each of the adjustment units, with a second position-limiting portion disposed on a bottom surface of each of the adjustment units, with a fourth free space disposed at each of the second position-limiting portions, allowing the first free space, the second free space, the third free space, and the fourth free space of each of the adjustment units to be in communication with each other.

In an embodiment of the present disclosure, each of the fixation units is movably disposed in the first free space, the second free space, the third free space, and the fourth free space of a corresponding one of the adjustment units.

In an embodiment of the disclosure, the second position-limiting portions each have a mounting portion, and the mounting portions are coupled to a bottom surface of the heat dissipation unit through a plurality of fixation components.

In an embodiment of the disclosure, an alignment portion is centrally disposed at each of the fixation units, with a first guiding portion and a second guiding portion disposed on two sides of each of the fixation units, and with a third guiding portion disposed on a bottom surface of each of the fixation units.

In an embodiment of the disclosure, the alignment portion of each of the fixation units is centrally disposed at a corresponding one of the adjustment units, and the first and second guiding portions of each of the fixation units are disposed on two sides of a corresponding one of the adjustment units, allowing the third guiding portion of each of the fixation units to be disposed on a bottom surface of a corresponding one of the adjustment units.

In an embodiment of the disclosure, the alignment portions each have a plurality of corresponding fastening holes.

Therefore, the present disclosure provides a heat dissipation device for an industrial computer to perform positional adjustment of fixation units movable in adjustment units and thereby enable the fixation units to precisely correspond in position to fastening holes of the industrial computer during a fastening process such that a heat dissipation unit is in full contact with a processor of the industrial computer after the heat dissipation unit has been coupled to the industrial computer, achieving enhanced ease of mounting, firm fastening, enhanced heat conduction efficiency, and satisfactory heat dissipation effect.

### BRIEF DESCRIPTION OF THE DRAWINGS

FIG. 1 is a first perspective view of an embodiment of the present disclosure.

FIG. 2 is a second perspective view of an embodiment of the present disclosure.

FIG. 3 is a first exploded view of an embodiment of the present disclosure.

FIG. 4 is a second exploded view of an embodiment of the present disclosure.

FIG. 5 is a first schematic view of the use of an embodiment of the present disclosure.

FIG. 6 is a second schematic view of the use of an embodiment of the present disclosure.

FIG. 7 is a third schematic view of the use of an embodiment of the present disclosure.

FIG. 8 is a fourth schematic view of the use of an embodiment of the present disclosure.

FIG. 9 is an exploded view of an embodiment of the present disclosure.

FIG. 10 is a perspective view of an embodiment of the present disclosure.

### DETAILED DESCRIPTION OF THE INVENTION

To facilitate understanding of the object, characteristics, and effects of the present disclosure, embodiments together with the attached drawings for the detailed description of the present disclosure are provided.

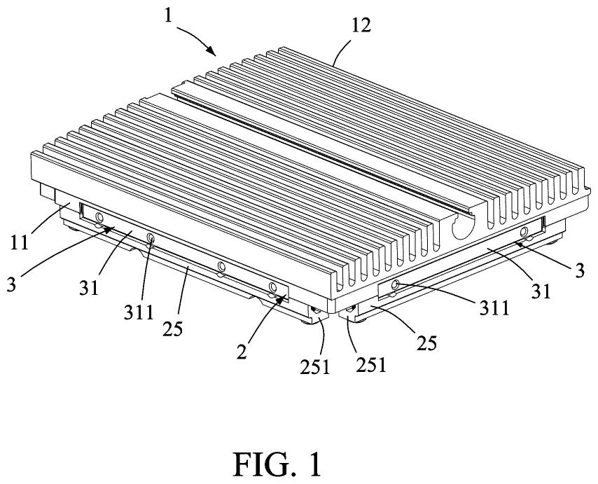

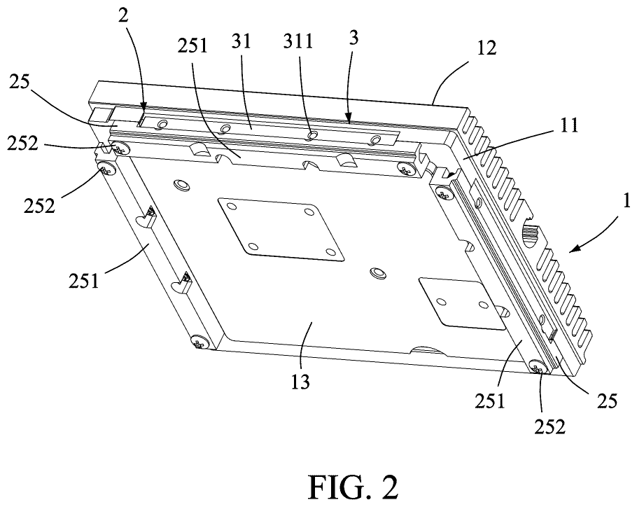

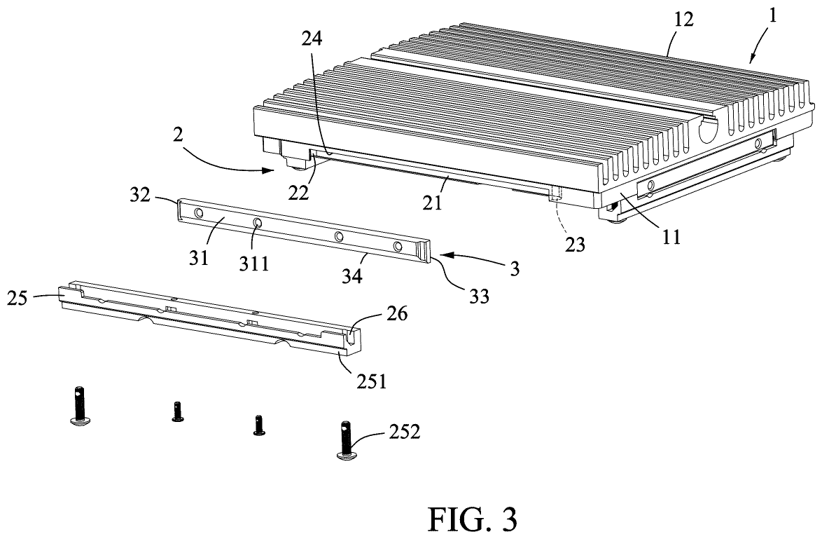

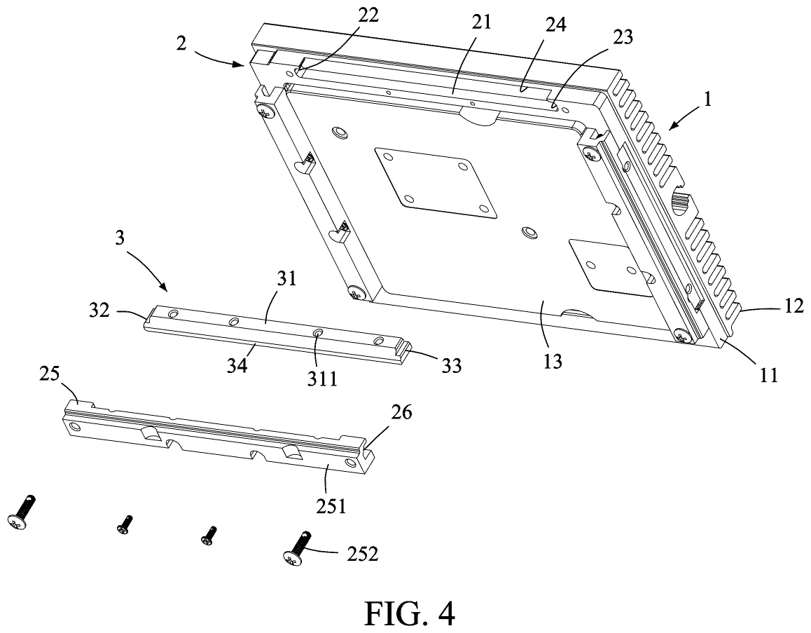

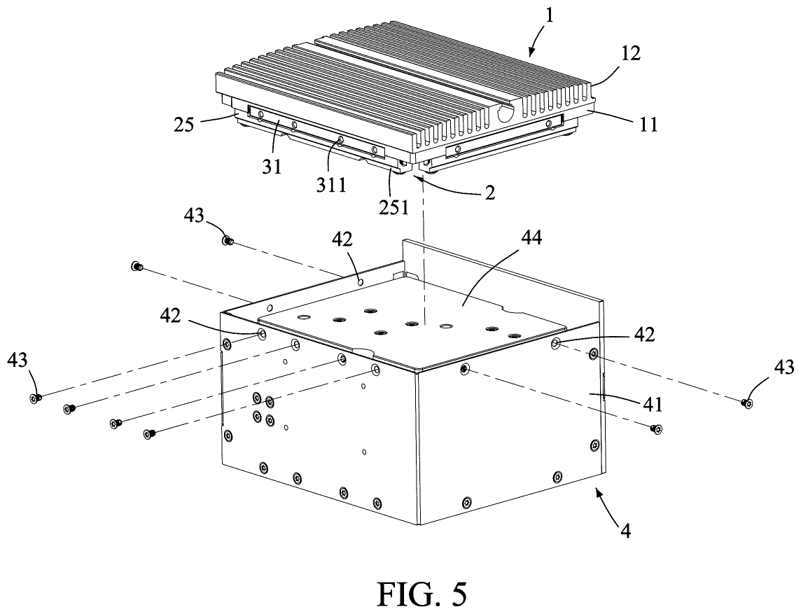

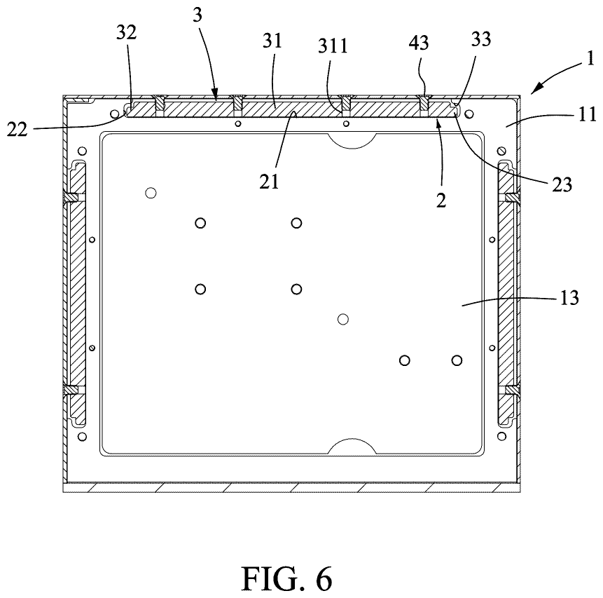

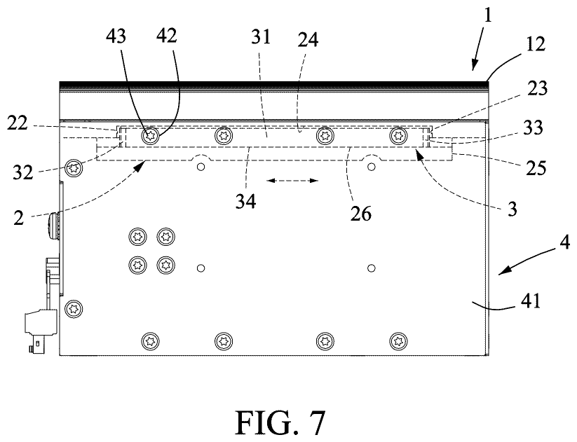

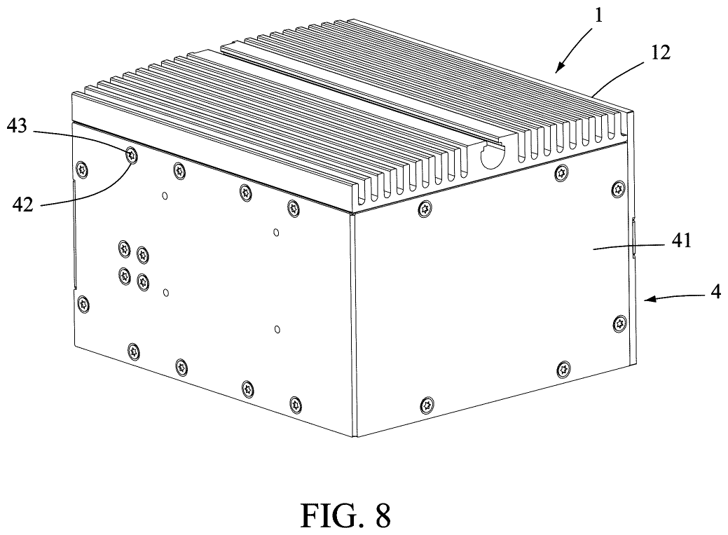

Referring to FIG. 1 through FIG. 8, an embodiment of the present disclosure provides a heat dissipation device for an industrial computer. The heat dissipation device comprises a heat dissipation unit 1, at least two adjustment units 2, and at least two fixation units 3.

The adjustment units 2 are disposed on at least two sides of the heat dissipation unit 1.

The fixation units 3 are movably disposed at the adjustment units 2.

The heat dissipation unit 1 has to be mounted on an industrial computer 4 to dissipate heat therefrom so as to start using the heat dissipation unit 1. The heat dissipation unit 1 is mounted on the industrial computer 4 through the steps as follows: placing the heat dissipation unit 1 on the top surface of a casing 41 of the industrial computer 4; pointing the fixation units 3 at a plurality of fastening holes 42 on the casing 41; and fastening a plurality of fixation components 43 to the fixation units 3 through the fastening holes 42. When there is manufacturing tolerance of the fastening holes 42 in terms of their positions on the casing 41, the fixation units 3 cannot correspond in position to the fastening holes 42 prior to the fastening step. The problem with tolerance is solved in a way as explained below. During the fastening step, the adjustment units 2 provide the fixation units 3 with movement spaces required for positional adjustment (mostly fine-tuning) of the fixation units 3 such that the fixation units 3 can precisely correspond in position to the fastening holes 42 on the casing 41, allowing the fixation components 43 to be firmly and precisely fastened to the fixation units 3 through the fastening holes 42. Thus, the bottom of the heat dissipation unit 1 is in full contact with a processor 44 of the industrial computer 4. Therefore, the heat dissipation device of the present disclosure features enhanced ease of mounting, firm fastening, enhanced heat conduction efficiency, and satisfactory heat dissipation effect.

In an embodiment of the present disclosure, the heat dissipation unit 1 comprises a base 11, a heatsink module 12 and a contact portion 13. The heatsink module 12 is disposed on the top surface of the base 11. The contact portion 13 is disposed on the bottom surface of the base 11. The adjustment units 2 are disposed on the lateral sides of the base 11. In an embodiment of the present disclosure, the adjustment units 2 are three in number and are disposed on three adjacent lateral sides of the base 11, with the three fixation units 3 disposed in the three adjustment units 2, and with the plurality of fastening holes 42 disposed on three adjacent lateral sides of the casing 41. Thus, the base 11 of the heat dissipation unit 1 is disposed on the top surface of the casing 41. During the fastening step, the adjustment units 2 provide the fixation units 3 with movement spaces required for the positional adjustment (mostly fine-tuning) of the fixation units 3 such that the fixation units 3 can precisely correspond in position to the fastening holes 42 on the casing 41, allowing the fixation components 43 to be firmly and precisely fastened to the fixation units 3 through the fastening holes 42. Therefore, not only is the problem with the manufacturing tolerance of the fastening holes 42 in terms of their positions on the casing 41 solved, but the contact portion 13 of the heat dissipation unit 1 fastened in place is also in full contact with the processor 44 of the industrial computer 4 to allow the contact portion 13 to easily take in heat from the processor 44 and then transfer the heat to the heatsink module 12 through the base 11 for heat dissipation. Therefore, the heat dissipation device of the present disclosure features enhanced ease of mounting, firm fastening, enhanced heat conduction efficiency, and satisfactory heat dissipation effect.

In an embodiment of the present disclosure, a first free space 21 is centrally disposed at each of the adjustment units 2, with a second free space 22 and a third free space 23 disposed on two sides of each of the adjustment units 2, with a first position-limiting portion 24 disposed on the top surface of each of the adjustment units 2, with a second position-limiting portion 25 disposed on the bottom surface of each of the adjustment units 2, and with a fourth free space 26 disposed at each of the second position-limiting portions 25. The first free space 21, the second free space 22, the third free space 23, and the fourth free space 26 of each of the adjustment units 2 are in communication with each other. Each of the second position-limiting portions 25 has a mounting portion 251, and the mounting portions 251 are coupled to the bottom surface of the base 11 of the heat dissipation unit 1 through a plurality of fixation components 252. Owing to the limitation function of the first position-limiting portion 24 and the second position-limiting portion 25, each of the fixation units 3 is movably disposed in the first free space 21, the second free space 22, the third free space 23, and the fourth free space 26 of a corresponding one of the adjustment units 2.

In an embodiment, the heat dissipation device of the present disclosure can be mounted on an industrial computer through the steps as follows: placing the base 11 of the heat dissipation unit 1 on the top surface of the casing 41, allowing the first free space 21, the second free space 22, the third free space 23, and the fourth free space 26 of the adjustment units 2 to function as movement spaces for the fixation units 3 during a fastening process, and limiting the adjustment of the movement of the fixation units 3 appropriately with the first position-limiting portion 24 and the second position-limiting portion 25 to perform the positional adjustment (mostly fine-tuning) of the fixation units 3 during the fastening process. Thus, the fixation units 3 can precisely correspond in position to the fastening holes 42 on the casing 41 to allow the fixation components 43 to be firmly and precisely fastened to the fixation units 3 through the fastening holes 42. Therefore, not only is the problem with the manufacturing tolerance of the fastening holes 42 in terms of their positions on the casing 41 solved, but the contact portion 13 of the heat dissipation unit 1 fastened in place is also in full contact with the processor 44 of the industrial computer 4 to allow the contact portion 13 to easily take in heat from the processor 44 and then transfer the heat to the heatsink module 12 through the base 11 for heat dissipation. Therefore, the heat dissipation device of the present disclosure features enhanced ease of mounting, firm fastening, enhanced heat conduction efficiency, and satisfactory heat dissipation effect.

In an embodiment of the present disclosure, an alignment portion 31 is centrally disposed at each of the fixation units 3 and has a plurality of corresponding fastening holes 311. A first guiding portion 32 and a second guiding portion 33 are disposed on two sides of each of the fixation units 31. A third guiding portion 34 is disposed on the bottom surface of each of the fixation units 3. The alignment portions 31 of the fixation units 3 correspond in position to the first free spaces 21 centrally disposed at the adjustment units 2. The first guiding portion 32 and the second guiding portion 33 of each of the fixation units 3 correspond in position to the second free space 22 and the third free space 23 disposed on two sides of a corresponding one of the adjustment units 2. The third guiding portion 34 of each of the fixation units 3 corresponds in position to the fourth free space 26 disposed on the bottom surface of a corresponding one of the adjustment units 2.

In an embodiment, mounting the heat dissipation device on the industrial computer 4 entails performing the steps described below. The base 11 of the heat dissipation unit 1 is placed on the top surface of the casing 41. During the fastening process, all of the first free spaces 21, the second free spaces 22, the third free spaces 23, and the fourth free spaces 26 of the adjustment units 2 function as movement spaces for the upward, downward, leftward, and rightward movements of the fixation units 3 with the assistance from the alignment portions 31, the first guiding portions 32, the second guiding portions 33 and the third guiding portions 34 of the fixation units 3 separately or simultaneously. The first position-limiting portion 24 and the second position-limiting portion 25 coordinate with the alignment portion 31 to appropriately limit the adjustment of the movement of the fixation units 3 when performing the positional adjustment (mostly fine-tuning) of the fixation units 3 during the fastening process. Thus, the fastening holes 311 of the alignment portions 31 of the fixation units 3 can precisely correspond in position to the fastening holes 42 on the casing 41 to allow the fixation components 43 to be firmly and precisely fastened to the fastening holes 311 of the alignment portions 31 through the fastening holes 42. Therefore, not only is the problem with the manufacturing tolerance of the fastening holes 42 in terms of their positions on the casing 41 solved, but the contact portion 13 of the heat dissipation unit 1 fastened in place is also in full contact with the processor 44 of the industrial computer 4 to allow the contact portion 13 to easily take in heat from the processor 44 and then transfer the heat to the heatsink module 12 through the base 11 for heat dissipation. Therefore, the heat dissipation device of the present disclosure features enhanced ease of mounting, firm fastening, enhanced heat conduction efficiency, and satisfactory heat dissipation effect.

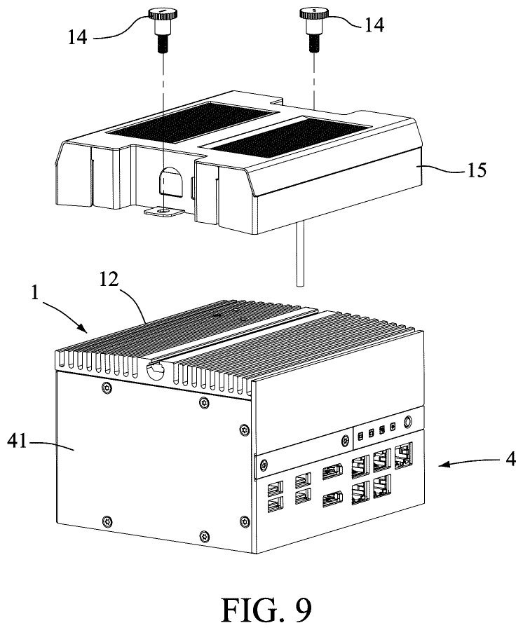

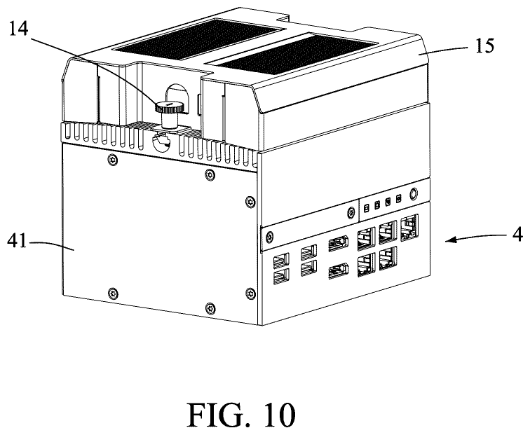

Referring to FIG. 9 and FIG. 10, in an embodiment of the present disclosure, the heat dissipation unit 1 further comprises a fitting portion 14 and a guiding module 15, with the heatsink module 12 disposed on the top surface of the base 11, with the contact portion 13 disposed on the bottom surface of the base 11, with the fitting portion 14 disposed at the heatsink module 12, with the guiding module 15 coupled to the fitting portion 14 and disposed on the top surface of the heatsink module 12.

In an embodiment, after the base 11 of the heat dissipation unit 1 has been fastened to the casing 41 of the industrial computer 4 through the adjustment units 2 and the fixation units 3, the contact portion 13 of the heat dissipation unit 1 is in full contact with the processor 44 of the industrial computer 4 to allow the contact portion 13 to steadily take in heat from the processor 44 and then transfer the heat to the heatsink module 12 through the base 11 for heat dissipation to be carried out through the heatsink module 12 and the guiding module 15. Therefore, the heat dissipation device of the present disclosure features enhanced ease of mounting, firm fastening, enhanced heat conduction efficiency, and satisfactory heat dissipation effect.

While the present disclosure has been described by means of specific embodiments, numerous modifications and variations could be made thereto by those skilled in the art without departing from the scope and spirit of the present disclosure set forth in the claims.

What is claimed is:

1. A heat dissipation device for an industrial computer, the heat dissipation device comprising:
a heat dissipation unit;
at least two adjustment units disposed on at least two sides of the heat dissipation unit; and
at least two fixation units movably disposed at the adjustment units.

2. The heat dissipation device for an industrial computer according to claim 1, wherein the heat dissipation unit comprises a base, a heatsink module and a contact portion, with the heatsink module disposed on a top surface of the base, and the contact portion disposed on a bottom surface of the base, allowing the adjustment units to be disposed on lateral sides of the base.

3. The heat dissipation device for an industrial computer according to claim 1, wherein the heat dissipation unit comprises a base, a heatsink module, a contact portion, a fitting portion, and a guiding module, with the heatsink module disposed on a top surface of the base, the contact portion disposed on a bottom surface of the base, the fitting portion disposed at the heatsink module, the guiding module coupled to the fitting portion and disposed on a top surface of the heatsink module, allowing the adjustment units to be disposed on lateral sides of the base.

4. The heat dissipation device for an industrial computer according to claim 1, wherein a first free space is centrally disposed at each of the adjustment units, with a second free space and a third free space disposed on two sides of each of the adjustment units, with a first position-limiting portion disposed on a top surface of each of the adjustment units, with a second position-limiting portion disposed on a bottom surface of each of the adjustment units, with a fourth free space disposed at each of the second position-limiting portions, allowing the first free space, the second free space, the third free space, and the fourth free space of each of the adjustment units to be in communication with each other.

5. The heat dissipation device for an industrial computer according to claim 4, wherein each of the fixation units is movably disposed in the first free space, the second free space, the third free space, and the fourth free space of a corresponding one of the adjustment units.

6. The heat dissipation device for an industrial computer according to claim 4, wherein the second position-limiting portions each have a mounting portion, and the mounting portions are coupled to a bottom surface of the heat dissipation unit through a plurality of fixation components.

7. The heat dissipation device for an industrial computer according to claim 1, wherein an alignment portion is centrally disposed at each of the fixation units, with a first guiding portion and a second guiding portion disposed on two sides of each of the fixation units, and with a third guiding portion disposed on a bottom surface of each of the fixation units.

8. The heat dissipation device for an industrial computer according to claim 7, wherein the alignment portion of each of the fixation units is centrally disposed at a corresponding one of the adjustment units, and the first and second guiding portions of each of the fixation units are disposed on two sides of a corresponding one of the adjustment units, allowing the third guiding portion of each of the fixation units to be disposed on a bottom surface of a corresponding one of the adjustment units.

9. The heat dissipation device for an industrial computer according to claim 7, wherein the alignment portions each have a plurality of corresponding fastening holes.
